(19) United States
(12) Patent Application Publication
(10) Pub. No.: US 2017/0213705 A1
(43) Pub. Date: Jul. 27, 2017

(54) SLIT VALVE GATE COATING AND METHODS FOR CLEANING SLIT VALVE GATES

(71) Applicant: APPLIED MATERIALS, INC., Santa Clara, CA (US)

(72) Inventors: OFER AMIR, Half Moon Bay, CA (US); JENNIFER Y. SUN, Mountain View, CA (US); MICHAEL R. RICE, Pleasanton, CA (US); MICHAEL C. KUCHAR, Georgetown, TX (US); JOSEPH F. SOMMERS, San Jose, CA (US)

(21) Appl. No.: 15/414,555

(22) Filed: Jan. 24, 2017

Related U.S. Application Data
(60) Provisional application No. 62/287,695, filed on Jan. 27, 2016.

(51) Int. Cl. H01J 37/32; B08B 3/12; H01L 21/67

(52) U.S. Cl. CPC H01J 37/32477; H01L 21/67069; H01J 37/32091; H01J 37/32853; B08B 3/12

(57) ABSTRACT

Slit valve gates and methods for cleaning are provided. Slit valves include: a slit valve gate configured to seal an opening of a process chamber, the slit valve gate comprising a surface that faces an processing volume of the process chamber; and a non-porous anodized coating on the surface of the slit valve gate. Methods of cleaning include: immersing the slit valve gate in a tank comprising deionized water; sonicating the slit valve gate at a first power density of about 6 W/cm² to about 15 W/cm² and a frequency of about 25 kHz to about 40 kHz for a first period of time; sonicating the slit valve gate at a second power density of about 30 W/cm² to about 45 W/cm² and a frequency of about 25 kHz to about 40 kHz for a second period of time; and removing the slit valve gate from the tank.

### CROSS-REFERENCE TO RELATED APPLICATIONS

This application claims benefit of U.S. provisional patent application Ser. No. 62/287,695, filed Jan. 27, 2016, which is herein incorporated by reference in its entirety.

### FIELD

Embodiments of the present disclosure generally relate to semiconductor substrate processing equipment.

### BACKGROUND

Semiconductor processing chambers utilize a slit valve gate to seal an opening in a wall of the process chamber used to provide access to the interior of the process chamber, so example to allow substrates or other workpieces to be inserted into or removed from the process chamber. Typically the surface of the slit valve gate facing the interior of the process chamber has an anodized coating. Currently, process chamber components, such as slit valve gates, are treated, for example by a hard anodizing process, resulting in the formation of a porous aluminum oxide layer on the process chamber component. Anodizing is typically an electrolytic oxidation process that produces an integral coating of relatively porous aluminum oxide on the aluminum surface. However, the inventors have observed that the slit valve gate flexes when the slit valve gate seals resulting in the potential for the coating to flake, undesirably resulting in contamination within the chamber.

Accordingly, the inventors have provided a substrate processing chamber having a slit valve gate with an improved coating and methods for cleaning a slit valve gate.

### SUMMARY

Embodiments of slit valve gates with improved coatings for use in a process chamber and methods for cleaning slit valve gates are provided herein. In some embodiments, a slit valve for use in a process chamber includes: a slit valve gate configured to seal an opening of a process chamber, wherein the slit valve gate comprises a surface that faces a processing volume of the process chamber; and a non-porous anodized coating formed on the surface of the slit valve gate. In some embodiments, the surface of the slit valve is fabricated from aluminum. The non-porous anodized coating may be an amorphous aluminum oxide coating.

In some embodiments, an apparatus for processing a substrate includes: a process chamber comprising a processing volume; an opening in a sidewall of the process chamber providing access to the processing volume; a slit valve gate configured to seal the opening, wherein the slit valve gate is as described in any of the embodiments disclosed herein.

In some embodiments, a method of cleaning a slit valve gate for sealing a process volume of a process chamber includes: immersing the slit valve gate in a tank comprising deionized water; sonicating the slit valve gate at a first power density of about 6 W/cm² to about 15 W/cm2 and a frequency of about 25 kHz to about 40 kHz for a first period of time; sonicating the slit valve gate at a second power density of about 30 W/cm² to about 45 W/cm² and a frequency of about 25 kHz to about 40 kHz for a second period of time; and removing the slit valve gate from the tank.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are therefore not to be considered limiting of the scope, for the disclosure may admit to other equally effective embodiments.

FIG. 1 depicts an apparatus having a slit valve gate with a coating in accordance with some embodiments of the present disclosure.

FIG. 2 depicts a flow chart of a method of cleaning a slit valve gate having a non-porous anodized coating in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

A substrate processing chamber having a slit valve gate with an improved coating and methods for cleaning a slit valve gate are provided herein. Embodiments of the present disclosure may advantageously reduce contaminant particles from the slit valve gate using a method of cleaning the slit valve gate and may advantageously reduce flaking of the slit valve gate coating. Although disclosed with respect to a slit valve gate, the teachings provided herein can also be applied to other components within substrate processing systems.

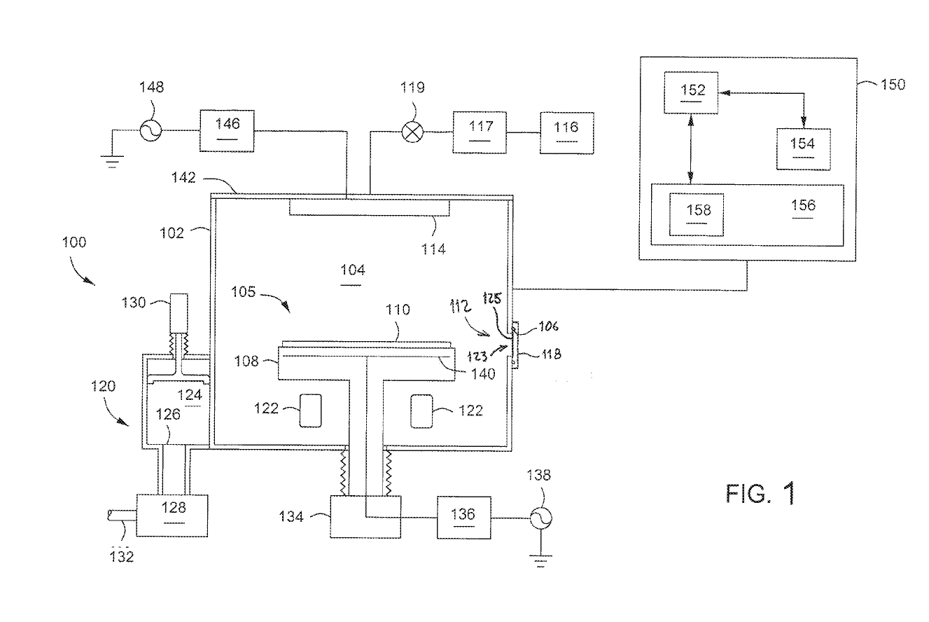

FIG. 1 depicts an apparatus 100 in accordance with some embodiments of the present disclosure. The apparatus 100 may comprise a controller 150 and a process chamber 102 having an exhaust system 120 for removing excess process gases, processing by-products, or the like, from the interior of the process chamber 102. Exemplary process chambers may include the DPS®, ENABLER®, ADVANTEDGE™, or other process chambers, available from Applied Materials, Inc. of Santa Clara, Calif. Other suitable process chambers having slit valves may similarly be modified in accordance with the teachings herein.

The process chamber 102 has an inner volume 105 that may include a processing volume 104. The processing volume 104 may be defined, for example, between a substrate support pedestal 108 disposed within the process chamber 102 for supporting a substrate 110 thereupon during processing and one or more gas inlets, such as a showerhead 114 and/or nozzles provided at predetermined locations.

A substrate 110 may enter the processing volume 104 of the process chamber 102 via an opening 112 in a sidewall of the process chamber 102. The opening 112 may be selectively sealed via a slit valve gate 118. Support components and actuating mechanisms to open and close the opening 112 with the slit valve gate 118 are well known and omitted for brevity. The slit valve gate comprises a surface 123 facing the processing volume 104. The slit valve gat may further comprise a gasket, such as o-ring 106, to facilitate sealing the opening 112 when the slit valve gate 118 is in the closed position. In some embodiments, the gasket (e.g., o-ring 106) is disposed in or on the surface 123. The slit valve gate 118, or at least the surface 123 is fabricated from process-compatible materials, such as aluminum. The surface 123 further comprises a non-porous anodized coating 125 disposed on the surface. In some embodiments, the non-porous anodized coating 125 has a thickness of about hundreds of nanometers to about 1 micrometer. For example, in some embodiments, the coating 125 may have a thickness of about 400 nm to about 1400 nm, or in some embodiments, about 800 nm to about 1200 nm. In some embodiments, the coating 125 may have a thickness of about 400 nm to about 500 nm.

The non-porous anodized coating 125 is an amorphous aluminum oxide coating. The coating 125 is formed by a suitable anodization process that forms an non-porous amorphous aluminum oxide coating to the desired thickness. Such a suitable process may be performed, for example, by Point Engineering, located in Chungnam, South Korea. In contrast, current anodization processes used to form coatings to the desired thickness create porous coatings, for example microcrystalline coatings, which tend to crack and release particles during operation of the slit valve gate. The inventors have discovered that the non-porous anodized coating 125 advantageously eliminates or reduces flaking from the slit valve gate 118 due to mechanical flexing of the slit valve gate 118, for example, as compared to porous anodized coatings.

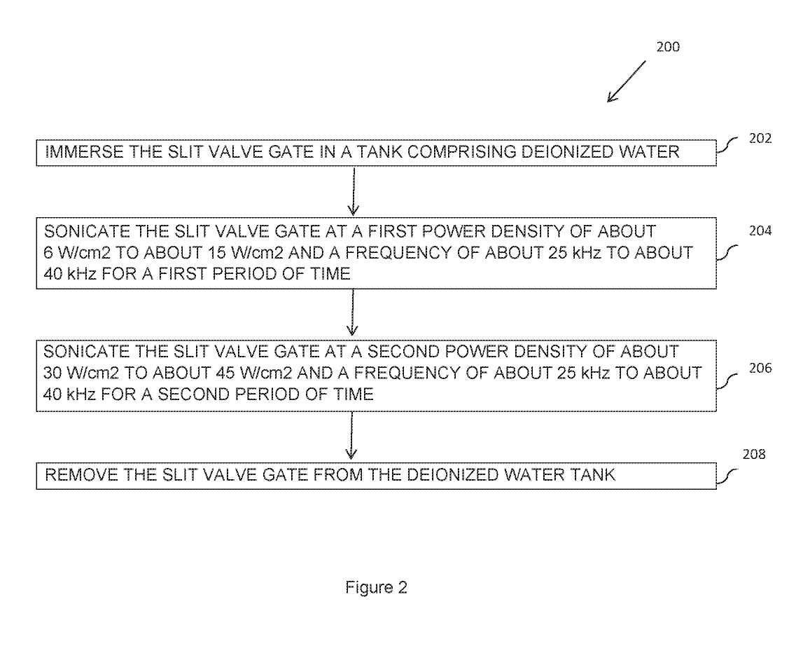

FIG. 2 depicts a flow chart of a method 200 for cleaning a slit valve gate having a non-porous anodized coating in accordance with some embodiments of the present disclosure. Although discussed in terms of cleaning a slit valve gate having a non-porous anodized coating, the method 200 may also be performed advantageously to clean other substrate processing components having similar non-porous anodized coatings, such as shields, liners, process kit components, or the like.

The method 200 generally begins at 202 by immersing the slit valve gate having the non-porous anodized coating in a tank comprising deionized water. Next, at 204, the slit valve gate having the non-porous anodized coating is sonicated at a first frequency and a first power density for a first period of time. The first frequency is about 25 kHz to about 40 kHz, or in some embodiments, about 40 kHz. The first power density can be about 6 W/cm² to about 15 W/cm², or in some embodiments, about 8 W/cm² to about 12 W/cm². The first period of time is about 15 minutes to about 45 minutes, or in some embodiments, about 30 minutes.

At 206, the slit valve gate having the non-porous anodized coating is sonicated at a second frequency and a second power density for a second period of time. The second frequency is about 25 kHz to about 40 kHz, or in some embodiments, about 40 kHz. In some embodiments, the first frequency and the second frequency are the same frequency. The second power density can be about 30 W/cm² to about 45 W/cm², or in some embodiments, about 30 W/cm² to about 35 W/cm². The second period of time is less than the first period of time and is about tens of seconds to about a few tens of minutes. For example, the second period of time can be about 30 seconds to about 60 seconds, or up to about 10 minutes. The duration of the second period of time is generally selected to prevent damage to the non-porous anodized coating and may vary given variation in one or more of the second frequency, the second power density, or the condition of the non-porous anodized coating.

In some embodiments, the slit valve gate having the non-porous anodized coating is sonicated under the conditions described at 204 first, then under the conditions described at 206. In some embodiments, the slit valve gate having the non-porous anodized coating is sonicated under the conditions described at 206 first, then under the conditions described at 204. In some embodiments, the slit valve gate having the non-porous anodized coating is alternately and repeatedly sonicated under the conditions described at 204 and 206 for a predetermined number of cycles, for a predetermined time, or until the slit valve gate is otherwise determined to be sufficiently clean. In some embodiments, the slit valve gate may be determined to be clean by monitoring particles present in the cleaning bath.

Once the contaminate particles from the slit valve gate are within acceptable tolerance levels, the method 200 proceeds to 208, where the slit valve gate is removed from the deionized water tank. In some embodiments, the slit valve gate is rinsed with deionized water to remove any loose particles and dried. The method 200 then generally ends and the slit valve gate may be reattached to the process chamber 102 described in FIG. 1.

Returning to FIG. 1, the substrate support pedestal 108 may be coupled to a lift mechanism 134 that may control the position of the substrate support pedestal 108 between a lower position (as shown) suitable for transferring substrates into and out of the chamber via the opening 112 and a selectable upper position suitable for processing. The process position may be selected to maximize process uniformity for a particular process. When in at least one of the elevated processing positions, the substrate support pedestal 108 may be disposed above the opening 112 to provide a symmetrical processing region.

In some embodiments, the substrate support pedestal 108 may include a mechanism that retains or supports the substrate 110 on the surface of the substrate support pedestal 108, such as an electrostatic chuck, a vacuum chuck, a substrate retaining clamp, or the like (not shown). In some embodiments, the substrate support pedestal 108 may include mechanisms for controlling the substrate temperature (such as heating and/or cooling devices, not shown) and/or for controlling the species flux and/or ion energy proximate the substrate surface.

For example, in some embodiments, the substrate support pedestal 108 may include an RF bias electrode 140. The RF bias electrode 140 may be coupled to one or more bias power sources (one bias power source 138 shown) through one or more respective matching networks (matching network 136 shown). The one or more bias power sources may be capable of producing up to 1200 W at a frequency of about 2 MHz to about 60 MHz, such as at about 2 MHz, or about 13.56 MHz, or about 60 Mhz. In some embodiments, two bias power sources may be provided for coupling RF power through respective matching networks to the RF bias electrode 140 at respective frequencies of about 2 MHz and about 13.56 MHz. In some embodiments, three bias power sources may be provided for coupling RF power through respective matching networks to the RF bias electrode 140 at respective frequencies of about 2 MHz, about 13.56 MHz, and about 60 Mhz. The at least one bias power source may provide either continuous or pulsed power. In some embodiments, the bias power source alternatively may be a DC or pulsed DC source.

The one or more gas inlets (e.g., the showerhead 114) may be coupled to a gas supply 116 for providing one or more process gases through a mass flow controller 117 into the processing volume 104 of the process chamber 102. In addition, one or more valves 119 may be provided to control the flow of the one or more process gases. The mass flow controller 117 and one or more valves 119 may be used individually, or in conjunction to provide the process gases at predetermined flow rates at a constant flow rate, or pulsed (as described above).

Although a showerhead 114 is shown in FIG. 1, additional or alternative gas inlets may be provided such as nozzles or inlets disposed in the ceiling or on the sidewalls of the process chamber 102 or at other locations suitable for providing gases to the process chamber 102, such as the base of the process chamber, the periphery of the substrate support pedestal, or the like.

In some embodiments, the apparatus 100 may utilize capacitively coupled RF power for plasma processing, although the apparatus may also or alternatively use inductive coupling of RF power for plasma processing. For example, the process chamber 102 may have a ceiling 142 made from dielectric materials and a showerhead 114 that is at least partially conductive to provide an RF electrode (or a separate RF electrode may be provided). The showerhead 114 (or other RF electrode) may be coupled to one or more RF power sources (one RF power source 148 shown) through one or more respective matching networks (matching network 146 shown). The one or more plasma sources may be capable of producing up to about 3,000 W, or in some embodiments, up to about 5,000 W at a frequency of about 2 MHz and/or about 13.56 MHz or a high frequency, such as 27 MHz and/or 60 MHz. The exhaust system 120 generally includes a pumping plenum 124 and one or more conduits that couple the pumping plenum 124 to the inner volume 105 (and generally, the processing volume 104) of the process chamber 102.

A vacuum pump 128 may be coupled to the pumping plenum 124 via a pumping port 126 for pumping out the exhaust gases from the process chamber via one or more exhaust ports (two exhaust ports 122 shown). The vacuum pump 128 may be fluidly coupled to an exhaust outlet 132 for routing the exhaust to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

To facilitate control of the process chamber 102 as described above, the controller 150 may be any form of general-purpose computer processor that can be used in an industrial setting for controlling various chambers and sub-processors. The memory, or computer-readable medium, 156 of the CPU 152 may be one or more of readily available memory such as random access memory (RAM), read only memory (ROM), floppy disk, hard disk, or any other form of digital storage, local or remote having software routines 158. The support circuits 154 are coupled to the CPU 152 for supporting the processor in a conventional manner. These circuits include cache, power supplies, clock circuits, input/output circuitry and subsystems, and the like.

Thus, embodiments of slit valve gates having non-porous anodized coatings, processing systems incorporating same, and methods for cleaning such slit valve gates are provided herein. The disclosed embodiments of the present disclosure may advantageously reduce contaminant particle formation resultant from the use or cleaning of the slit valve gate. Although discussed in terms of a slit valve gate having a non-porous anodized coating, the embodiments disclosed herein may also be applied advantageously to other substrate processing components. For example, a similar non-porous anodized coating may be provided on other substrate processing components, such as shields, liners, process kit components, or the like.

While the foregoing is directed to embodiments of the present disclosure, other and further embodiments of the disclosure may be devised without departing from the basic scope thereof.

1. A slit valve for use in a process chamber, comprising:
a slit valve gate configured to seal an opening of a process chamber, wherein the slit valve gate comprises a surface that faces a processing volume of the process chamber; and
a non-porous anodized coating formed on the surface of the slit valve gate.

2. The slit valve of claim 1, wherein the non-porous anodized coating has a thickness of about 400 nanometers to about 1400 nanometers.

3. The slit valve of claim 1, wherein the non-porous anodized coating has a thickness of about 800 nanometers to about 1200 nanometers.

4. The slit valve of claim 1, wherein the non-porous anodized coating has a thickness of about 400 nanometers to about 500 nanometers.

5. The slit valve of claim 1, wherein the non-porous anodized coating is an amorphous aluminum oxide coating.

6. The slit valve of claim 1, wherein the surface of the slit valve is fabricated from aluminum.

7. The slit valve of claim 1, further comprising a gasket disposed in or on the surface of the slit valve gate to facilitate forming a seal about the opening of the process chamber when the slit valve gate is in a closed position.

8. An apparatus for processing a substrate, comprising:
a process chamber comprising a processing volume;
an opening in a sidewall of the process chamber providing access to the processing volume;
a slit valve gate configured to seal the opening, wherein the slit valve gate comprises a surface facing the processing volume; and
a non-porous anodized coating formed on the surface of the slit valve gate.

9. The apparatus of claim 8, wherein the non-porous anodized coating has a thickness of about 400 nanometers to about 1400 nanometers.

10. The apparatus of claim 8, wherein the non-porous anodized coating has a thickness of about 800 nanometers to about 1200 nanometers.

11. The apparatus of claim 8, wherein the non-porous anodized coating has a thickness of about 400 nanometers to about 500 nanometers.

12. The apparatus of claim 8, wherein the non-porous anodized coating is an amorphous aluminum oxide coating.

13. The apparatus of claim 8, wherein the surface of the slit valve gate is fabricated from aluminum.

14. The apparatus of claim 8, further comprising a gasket disposed in or on the surface of the slit valve gate to facilitate forming a seal about the opening of the process chamber when the slit valve gate is in a closed position.

15. A method of cleaning a slit valve gate for sealing a process volume of a process chamber, comprising:
immersing the slit valve gate in a tank comprising deionized water;
sonicating the slit valve gate at a first power density of about 6 W/cm² to about 15 W/cm² and a frequency of about 25 kHz to about 40 kHz for a first period of time;
sonicating the slit valve gate at a second power density of about 30 W/cm² to about 45 W/cm² and a frequency of about 25 kHz to about 40 kHz for a second period of time; and
removing the slit valve gate from the tank.

16. The method of claim 15, wherein the second period of time is less than the first period of time.

17. The method of claim 15, wherein the first period of time is about 15 minutes to about 45 minutes.

18. The method of claim 17, wherein the second period of time is about tens of seconds to about a few tens of minutes.

19. The method of claim 15, wherein the slit valve gate includes a non-porous anodized coating disposed on a process volume facing surface of the slit valve gate.

20. The method of claim 15, wherein the slit valve gate is alternately and repeatedly sonicated at the first power density and the second power density.
